(19) United States
(12) Patent Application Publication
(10) Pub. No.: US 2011/0284883 A1
(43) Pub. Date: Nov. 24, 2011

(54) SEMICONDUCTOR LIGHT-EMITTING ELEMENT, LIGHT-EMITTING DEVICE, LUMINAIRE, DISPLAY UNIT, TRAFFIC SIGNAL LAMP UNIT, AND TRAFFIC INFORMATION DISPLAY UNIT

(75) Inventor: Shuhei SUDA, Joyo-shi (JP)

(73) Assignee: SEIWA ELECTRIC MFG. CO., LTD., Joyo-shi (JP)

(21) Appl. No.: 13/114,796

(22) Filed: May 24, 2011

(30) Foreign Application Priority Data
May 24, 2010 (JP) 2010-118461

(51) Int. Cl. H01L 33/62

(52) U.S. Cl. 257/88; 257/99; 257/E33.062

(57) ABSTRACT

Provided is a light-emitting element in which two LED structures are dividedly formed on a rectangular substrate. The LED structures are each a semiconductor layer made by laminating an n-type semiconductor layer (a LED structure), an active layer (not shown), and a p-type semiconductor layer, and are respectively provided near both ends of a diagonal line of the upper surface of the substrate. On the upper surface of the substrate, two bonding electrodes each having a circular surface are also respectively formed near both ends of the other diagonal line, and two resistance elements each formed of the n-type semiconductor layer are respectively provided near two opposite sides of the substrate.

### CROSS-REFERENCE TO RELATED APPLICATIONS

This Nonprovisional application claims priority under 35 U.S.C. § 119(a) on Patent Application No. 2010-118461 filed in Japan on May 24, 2010, the entire contents of which are hereby incorporated by reference.

### BACKGROUND

1. Technical Field

The present invention relates to a semiconductor light-emitting element in which a semiconductor layer is provided on a substrate by laminating an n-type semiconductor layer, an active layer, and a p-type semiconductor layer, a light-emitting device provided with the semiconductor light-emitting element, and a luminaire, a display unit, a traffic signal lamp unit, and a traffic information display unit each provided with the light-emitting devices.

2. Description of Related Art

In recent years, light-emitting diodes have been getting notice as light sources because they consume less electricity and have longer lives as compared with fluorescent lamps, incandescent lamps, etc. that have been heretofore used as light sources. At present, light-emitting diodes have been used in broad applications such as luminaire switches, light sources for backlights, light sources for illumination, decorations for amusements, etc. in addition to light sources for luminaires.

Of such light-emitting diodes, some can emit light of a single needed color such as blue light, bluish green light, green light, red light, or the like in accordance with their uses, and some can emit multicolor light, i.e., red light, green light, and blue light as individual packages. And further, another light-emitting diode has become commercial that can emit white light in combination with a fluorescent material.

For example, a white light-emitting diode (a white light-emitting device) has been disclosed that has an envelope portion in which a LED chip (a semiconductor light-emitting element) is enveloped, that contains a fluorescent material that produces light by being excited with light of a predetermined wavelength, and that has high luminous efficiency and luminous intensity (see Japanese Patent Application Laid-Open No. 2004-161789, for example).

### SUMMARY OF THE INVENTION

In the light-emitting diode (the light-emitting device) disclosed in Japanese Patent Application Laid-Open No. 2004-161789), however, only one LED chip (semiconductor light-emitting element) is provided in the package; therefore, to obtain desired brightness, there has been a need to design an external circuit in order to pass a current the value of which corresponds to the brightness. Moreover, to prevent the light-emitting diode against static electricity and overvoltage, there has been a necessity to connect a Zener diode or the like to the external circuit as a protective element, which has resulted in an increased component count and an increased production cost. In particular, in apparatus and so on in which a large number of light-emitting diodes are used, the number of protective elements, such as Zener diodes, increases as the number of the light-emitting diodes increases, and therefore some problems have arisen from the viewpoints of low component count, a space saving, and a low production cost.

The present invention has been accomplished under the circumstances, and thus it is an object of the present invention to provide a semiconductor light-emitting element that can be protected against static electricity and overvoltage without providing any external protective element, a light-emitting device provided with the semiconductor light-emitting element, and a luminaire, a display unit, a traffic signal lamp unit, and a traffic information display unit that are provided with the light-emitting devices.

A semiconductor light-emitting element according to the present invention is a semiconductor light-emitting element in which a semiconductor layer is provided on a substrate by laminating an n-type semiconductor layer, an active layer, and p-type semiconductor layer and that includes a first bonding electrode connected to one of the n-type and p-type semiconductor layers of the semiconductor layer, an n-type semiconductor layer as a first resistance element dividedly formed of the semiconductor layer on the substrate, a second bonding electrode and a first electrode that are formed on the upper surface of the n-type semiconductor layer as the first resistance element with a spacing provided between both the electrodes, and a first wiring layer connecting the first electrode and the other-type semiconductor layer of the semiconductor layer.

Another semiconductor light-emitting element according to the invention includes another semiconductor layer dividedly formed of the semiconductor layer on the substrate, a second wiring layer not only connecting the n-type semiconductor layer of the semiconductor layer and the p-type semiconductor layer of the divided semiconductor layer but connecting the p-type semiconductor layer of the semiconductor layer and the n-type semiconductor layer of the divided semiconductor layer.

Another semiconductor light-emitting element according to the invention includes a n-type semiconductor layer as a second resistance element dividedly formed of the semiconductor layer on the substrate, the first bonding electrode and a second electrode that are formed on the upper surface of the n-type semiconductor layer as the second resistance element with a spacing provided between both the elements, and a third wiring layer connecting the second electrode and one of the n-type and p-type semiconductor layers of the semiconductor layer.

In the semiconductor light-emitting element according to the invention, the substrate is shaped into a rectangle, the semiconductor layers are respectively provided near both ends of one diagonal line of the upper surface of the substrate, the bonding electrodes are respectively provided near both ends of the other diagonal line of the upper surface of the substrate, and the n-type semiconductor layer as the resistance element is provided near at least one side of the upper surface of the substrate.

In the semiconductor light-emitting element according to the invention, a resistance value for the n-type semiconductor layers as the resistance elements is 100 Ω to 5000 Ω.

The light-emitting device according to the present invention is provided with any one of the semiconductor light-emitting elements according to the invention and a housing portion in which the semiconductor light-emitting element is housed.

The luminaire according to the present invention is provided with the light-emitting devices according to the invention.

The display unit according to the present invention is provided with the light-emitting devices according to the invention.

The traffic signal lamp unit according to the present invention is provided with the light-emitting devices according to the invention.

The traffic information display unit according to the present invention is provided with the light-emitting devices according to the invention.

The semiconductor light-emitting element according to the invention includes the first bonding electrode connected to one of the n-type and p-type semiconductor layer of the semiconductor layer, the n-type semiconductor layer as the first resistance element dividedly formed of the semiconductor layer on the substrate, the second bonding electrode and the first electrode that are provided on the upper surface of the n-type semiconductor layer as the first resistance element with the spacing provided between both the electrodes, and the first wiring layer connecting the first electrode and the other-type semiconductor layer of the semiconductor layer. Thus the resistance element formed of the n-type semiconductor layer are connected in series to the LED structure (the semiconductor layer), i.e., the resistance element is also included in one semiconductor light-emitting element; therefore, there is no need to provide an external resistance element used for setting a current value, and a lower component count, a further space saving, and a lower production cost can be achieved; moreover, there is no need to design a circuit for setting the value of a current to be passed through the LED to obtain desired brightness, and the desired brightness can, therefore, be obtained just by applying a predetermined voltage.

The semiconductor light-emitting element according to the invention includes another semiconductor layer dividedly formed of the semiconductor layer on the substrate and the second wiring layer not only connecting the n-type semiconductor layer of the semiconductor layer and the p-type semiconductor layer of the divided semiconductor layer but connecting the p-type semiconductor layer of the semiconductor layer and the n-type semiconductor layer of the divided semiconductor layer. That is, the n-type semiconductor layer of one of the semiconductor layers is connected with the p-type semiconductor layer of the other semiconductor layer by using a wiring layer, and the p-type semiconductor layer of the former semiconductor layer is connected with the n-type semiconductor layer of the latter semiconductor layer by using a wiring layer. In the above case, i.e., the case where a pair of LED structures (semiconductor layers) connected in inverse parallel are provided in one semiconductor light-emitting element, when having using one of the LED structures as a light-emitting element, the other LED structure decreases static electricity and overvoltage to be applied to the former LED structure, and the semiconductor light-emitting element can, therefore, be protected against static electricity and overvoltage without providing any external protective element, whereby a low component count, a space saving, and a low production cost can be achieved.

The semiconductor light-emitting element according to the invention includes the n-type semiconductor layer as the second resistance element dividedly formed of the semiconductor layer on the substrate, the first bonding electrode and the second electrode that are formed on the upper surface of the n-type semiconductor layer as the second resistance element with a spacing provided between both the electrodes, and the third wiring layer connecting the second electrode and one of the n-type and p-type semiconductor layers of the semiconductor layer. Thus the resistance elements each formed of the n-type semiconductor layer are connected in series to the LED structures (the semiconductor layers), whereby an adjustment range of resistance values for the resistance elements can be extended; and further, there is no need to design a circuit for setting the value of a current to be passed through the LEDs to obtain desired brightness, and the desired brightness can, therefore, be obtained just by applying a predetermined voltage.

In the semiconductor light-emitting element according to the invention, the substrate is shaped into a rectangle, the two semiconductor layers are formed on the substrate, i.e., are respectively formed near both ends of one diagonal line of the upper surface of the substrate, the bonding electrodes are respectively formed near both ends of the other diagonal line of the upper surface of the substrate, and the n-type semiconductor layer is formed near at least one side of the upper surface of the substrate. That is, two LED structures and two resistance element can be included in one package, and one of the LED structures functions as a protective element that protects the other LED structure against static electricity and overvoltage; thus a semiconductor light-emitting element can be implemented to which there is no need to provide an external circuit, which can be protected against static electricity and overvoltage, and from which desired brightness can be obtained just by applying a predetermined voltage.

In the semiconductor light-emitting element according to the invention, a resistance value for the n-type semiconductor layers as the resistance elements is 100 Ω to 5000 Ω. A desired resistance value can be obtained by changing the length, width, and thickness of the n-type semiconductor layers. Therefore there is no need to design a circuit for setting the value a current to be passed through the LEDs to obtain desired brightness, and the desired brightness can be obtained just by applying a predetermined voltage.

The light-emitting device according to the invention is provided with the semiconductor light-emitting element described above. Therefore a light-emitting device can be provided which can be protected against static electricity and overvoltage, in which a low component count and a space saving can be achieved, and which can be fabricated at a low cost.

According to the present invention, by mounting the light-emitting device describe above, a luminaire, a display unit, a traffic signal lamp unit, and a traffic information display unit can be provided which can be protected against static electricity and overvoltage, in which low component counts and space savings can be achieved, and which can be produced at low costs.

In the present invention, since resistance elements each formed of a n-type semiconductor layer are connected in series to LED structures (semiconductor layers), i.e., since resistance elements are also included in one semiconductor light-emitting element, there is no need to provide an external circuit used for setting a current value, and a lower component count, a further space saving, and a lower production cost can, therefore, be implemented; and furthermore, there is no need to design a circuit for setting the value of a current to be passed through the LEDs to obtain desired brightness, and the desired brightness can, therefore, be obtained just by applying a predetermined voltage.

The above and further objects and features of the invention will more fully be apparent from the following detailed description with accompanying drawings.

### BRIEF DESCRIPTION OF THE SEVERAL VIEWS OF THE DRAWINGS

FIG. 1 is a schematic view of a semiconductor light-emitting element according to a first embodiment of the present invention showing an exemplary planar structure of the semiconductor light-emitting element;

FIG. 2 is a cross-sectional view of the semiconductor light-emitting element according to the first embodiment showing an exemplary cross-sectional structure of the semiconductor light-emitting element;

FIG. 3 is a circuit diagram of the semiconductor light-emitting element according to the first embodiment;

FIG. 4 is a schematic view of the semiconductor light-emitting element according to the first embodiment showing an exemplary arrangement of various components;

FIG. 5 is an explanatory drawing of the first half of a process of producing the semiconductor light-emitting element;

FIG. 6 is an explanatory drawing of the latter half of the process of producing the semiconductor light-emitting element;

FIG. 7 is schematic view of a semiconductor light-emitting element according to a second embodiment of the invention showing an exemplary arrangement of various components;

FIG. 8 is schematic view of a semiconductor light-emitting element according to a third embodiment of the invention showing an exemplary arrangement of several components;

FIG. 9 is a schematic view of a light-emitting device according to another embodiment of the invention showing an exemplary structure of the light-emitting device;

FIG. 10 is a schematic view of a luminaire according to another embodiment of the invention showing an exemplary structure of the luminaire;

FIG. 11 is a schematic view of a display unit according to another embodiment of the invention showing an exemplary structure of the display unit;

FIG. 12 is a schematic view of a traffic signal lamp unit according to another embodiment of the invention showing an exemplary structure of the traffic signal lamp unit; and

FIG. 13 is a schematic view of a traffic information display unit according to another embodiment of the invention showing an exemplary structure of the traffic information display unit.

### DETAILED DESCRIPTION

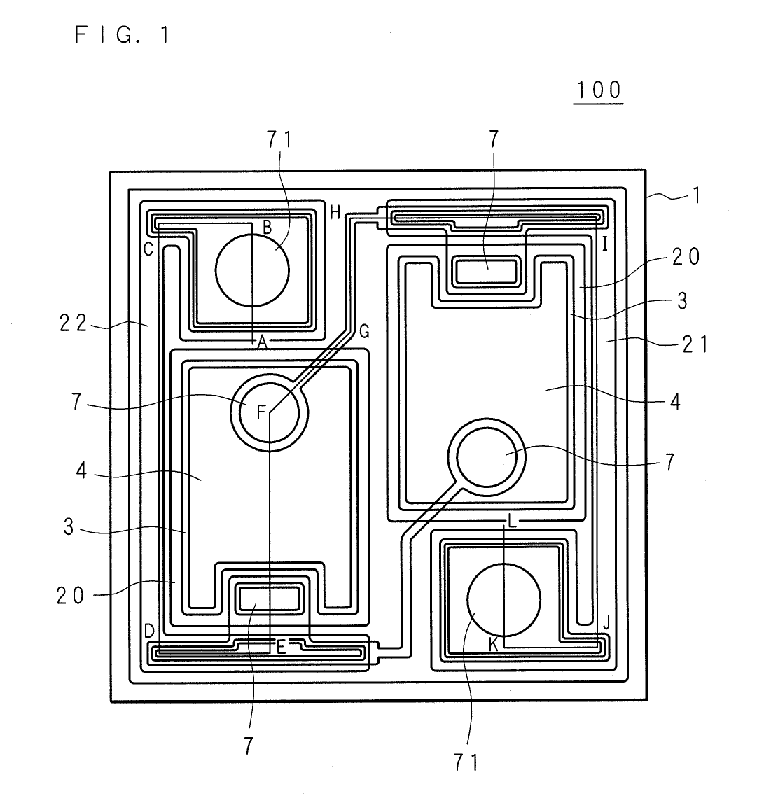

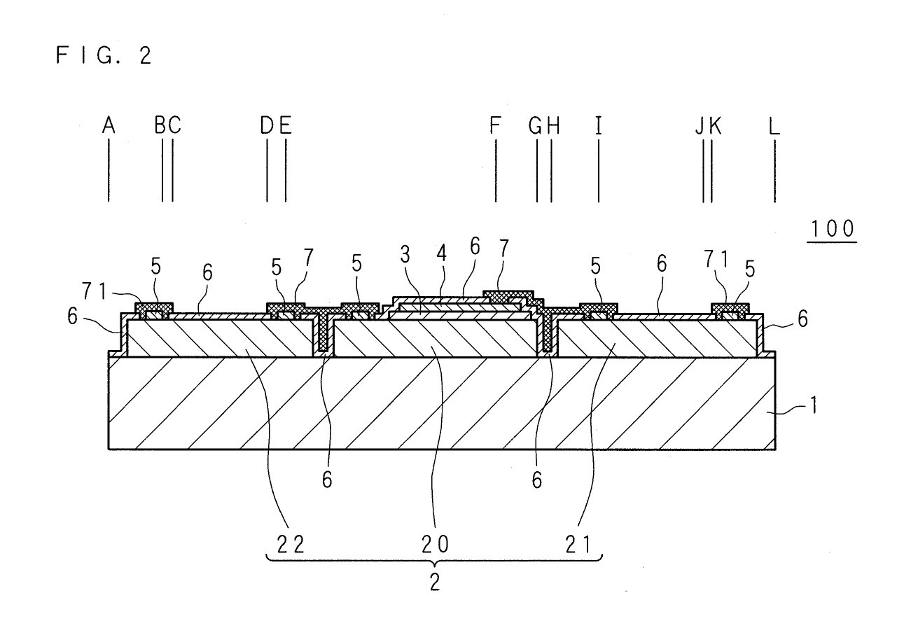

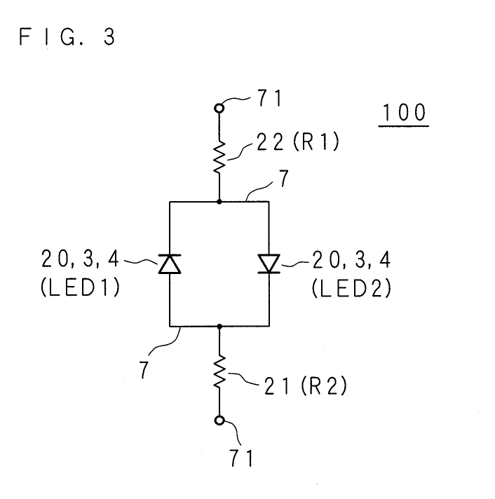

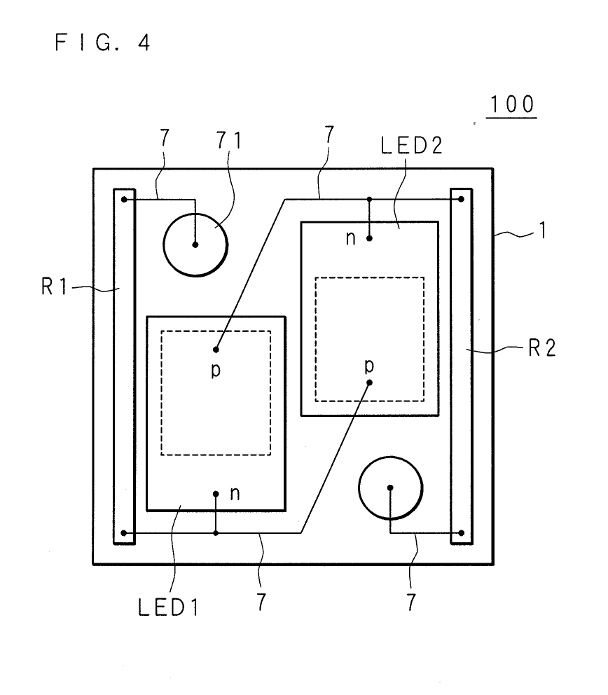

The present invention will be described below with reference to the drawings depicting several embodiments of the invention. FIG. 1 is a schematic view of a semiconductor light-emitting element 100 according to a first embodiment of the present invention showing an exemplary planar structure of the semiconductor light-emitting element 100; FIG. 2 is a cross-sectional view of the semiconductor light-emitting element 100 according to the first embodiment showing an exemplary cross-sectional structure of the semiconductor light-emitting element 100; FIG. 3 is circuit diagram of the semiconductor light-emitting element 100 according to the first embodiment; and FIG. 4 is a schematic view of the semiconductor light-emitting element 100 according to the first embodiment showing an exemplary arrangement of various components. Incidentally, FIG. 2 is an illustration showing a longitudinal section of the semiconductor light-emitting element 100 indicated by a line made by linking up places represented by reference characters A to L in FIG. 1. In addition, FIG. 4 is an illustration schematically showing the planar structure depicted as FIG. 1; for example, in spite of having a width, a wiring layer 7 is schematically shown as a line segment for the sake of convenience.

The semiconductor light-emitting element 100 (hereinafter also referred to as “light-emitting element”) according to this embodiment is each of a plurality of light-emitting elements produced by cutting a wafer (on which the light-emitting elements are formed) such that each light-emitting element has a shape of a rectangular parallelepiped and predetermined dimensions, and is, therefore, a LED chip, for example. In FIGS. 1 and 2, reference numeral 1 denotes a sapphire substrate. The sapphire substrate 1 (hereinafter referred to as “substrate”) has rectangular upper and lower surfaces, and has dimensions of about 0.35 mm in length and width, for example; however, the dimensions of the sapphire substrate 1 are not limited to such values.

As shown in FIGS. 1 and 4, on the rectangular substrate 1 of the light-emitting element 100, two LED structures (LEDs 1 and 2) are respectively provided near the two ends of one diagonal line of the upper surface of the substrate 1 by individually laminating an n-type semiconductor layer 20, an active layer (not shown), and a p-type semiconductor layer 3 as a semiconductor layer. And further, two bonding electrodes (bonding pads) 71 having a circular surface are respectively formed near the two ends of the other diagonal line of the substrate 1. The bonding electrodes 71 are each an electrode for bonding a wire between the light-emitting element 100 and an external circuit (such as an external electrode or a lead wire). In addition, on the upper surface of the substrate 1, two resistance elements R1 and R2, which are respectively formed of n-type semiconductor layers (resistance elements) 22 and 21, are respectively formed near two opposite sides of the substrate 1.

As shown in FIGS. 3 and 4, one of the bonding electrodes 71 is connected with one end of the resistance element R1 constituted by the n-type semiconductor layer 22 through a medium of the wiring layer 7. The other end of the resistance element R1 is connected with the cathode of the LED 1 and the anode of the LED 2 through the medium of the wiring layer 7. Likewise, the other bonding electrode 71 is connected with one end of the resistance element R2 constituted by the n-type semiconductor layer 21 through the medium of the wiring layer 7. The other end of the resistance element R2 is connected with the anode of the LED 1 and the cathode of the LED 2 through the medium of the wiring layer 7.

In FIGS. 1 and 2, reference characters A and B denote one of the bonding electrodes 71, reference characters C and D denote the n-type semiconductor layer 22 as the resistance element R1, reference characters E and F denote the LED structure (the LED 1), reference characters I and J denote the n-type semiconductor layer 21 as the resistance element R2, and reference characters K and L denote the other bonding electrode 71.

The LED structures of FIGS. 1 and 2 are each made by laminating an AlN buffer layer (not shown), an about-2-μm-thick undoped GaN layer (not shown), the n-type semiconductor layer 20, the active layer (not shown), and the p-type semiconductor layer 3 on the substrate 1 in that order. The n-type semiconductor layer 20 is constituted by an about-2-μm-thick n-GaN (gallium nitride) layer, an n-AlGaInN clad layer, etc., for example. The active layer is constituted by a GaN/InGaN-MQW (multi-quantum-well) active layer etc. The p-type semiconductor layer 3 is constituted by a p-AlGaInN layer, an about-0.3-μm-thick p-GaN layer, a p-InGaN layer as a contact layer, etc. As a result of these, compound semiconductor layers are formed, that is, the LED structures (the LEDs 1 and 2) are provided as semiconductor layers. Incidentally, the LED structures may be formed without providing the undoped GaN layer.

On the upper surface of each p-type semiconductor layer 3, a current-diffusing layer 4 is formed. Examples of the current-diffusing layer 4 include an ITO (indium-tin oxide) film as a conductive transparent film. At part of each semiconductor layer, an n-type ohmic electrode 5 is formed on a surface of the n-type semiconductor layer 20 exposed by removing part of the p-type semiconductor layer 3 and part of the active layer by means of etching or the like.

Each ohmic electrode 5 can be made by depositing a V-Au-Al-Ni-Au film, for example, by means of vacuum evaporation, patterning the film by using a lift-off method, and heating the laminated piece to a temperature of about 500° C. in a mixed nitrogen-oxygen atmosphere. The ohmic electrodes 5 are portions where electrical junction with the n-type semiconductor layer 20 is established.

Incidentally, although only one of the semiconductor layers (only the LED structure, i.e., only the LED 1) is shown in FIG. 2, the other semiconductor layer (i.e., the LED 2) also has the same structure as the structure of the LED 1.

On the substrate 1, the n-type semiconductor layer 21, and 22 as the resistance element are formed at a spacing from two semiconductor layers (the LED structure, i.e., the LED 1, and 2). The n-type semiconductor layer 22 and 21 are each constituted by an about-2-μm-thick n-GaN (gallium nitride) layer, an n-AlGaInN clad layer, etc. for example. On the upper surface of each of the n-type semiconductor layers 22 and 21, two n-type ohmic electrodes 5 are formed with a proper spacing provided between the two electrodes 5.

At portions where no n-type ohmic electrode 5 is formed of the side surfaces and the upper surfaces of the n-type semiconductor layers 22, 20, and 21, the p-type semiconductor layer 3, the current-diffusing layer 4, etc., SiO₂ films 6, e.g., are deposited as protective films.

At one of the two n-type ohmic electrodes 5 of each of the n-type semiconductor layers 22 and 21, a bonding electrode 71 is formed. The bonding electrodes 71 can be made by depositing Ti-Au films, for example, through vacuum evaporation. Since the Ti-Au alloy is used as a material for the bonding electrodes 71, the bonding electrodes 71 are high in mechanical strength, easy of bonding, and hard to peel off. Incidentally, as the material for the bonding electrodes 71, a metal such as a Ni-Au alloy can also be used.

The other n-type ohmic electrode 5 of each of the n-type semiconductor layers 22 and 21 is electrically connected with the n-type ohmic electrodes 5 formed on the n-type semiconductor layer 20 and the current-diffusing layer 4 via the wiring layers 7. The wiring layers 7 can be made by depositing Ti-Au films, for example, through vacuum evaporation.

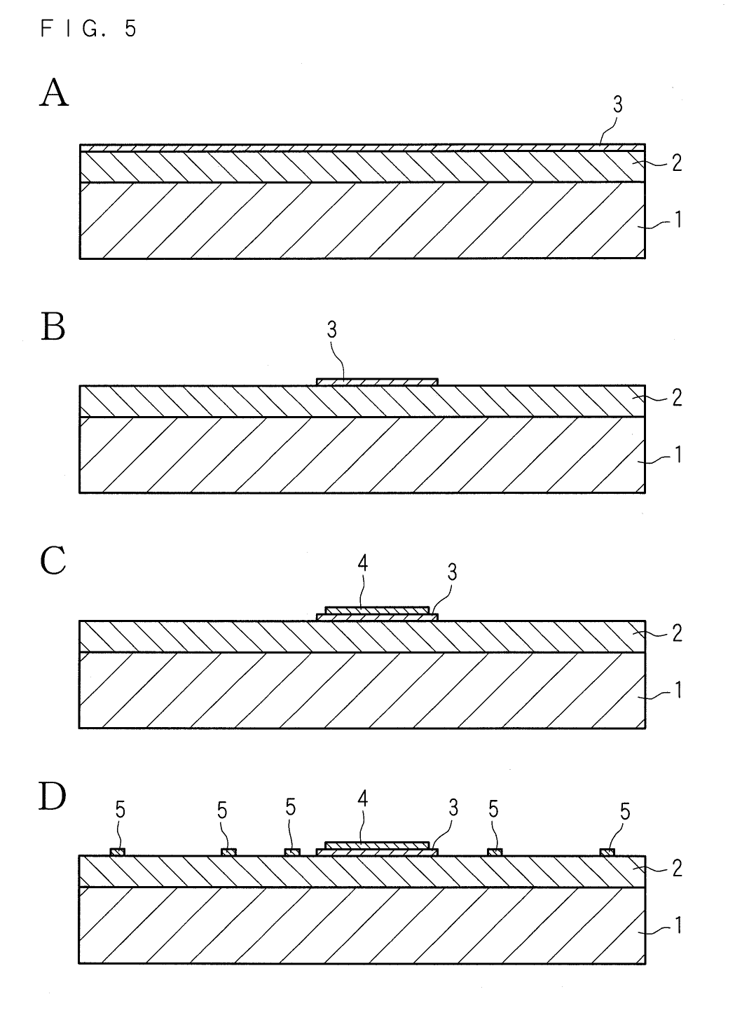

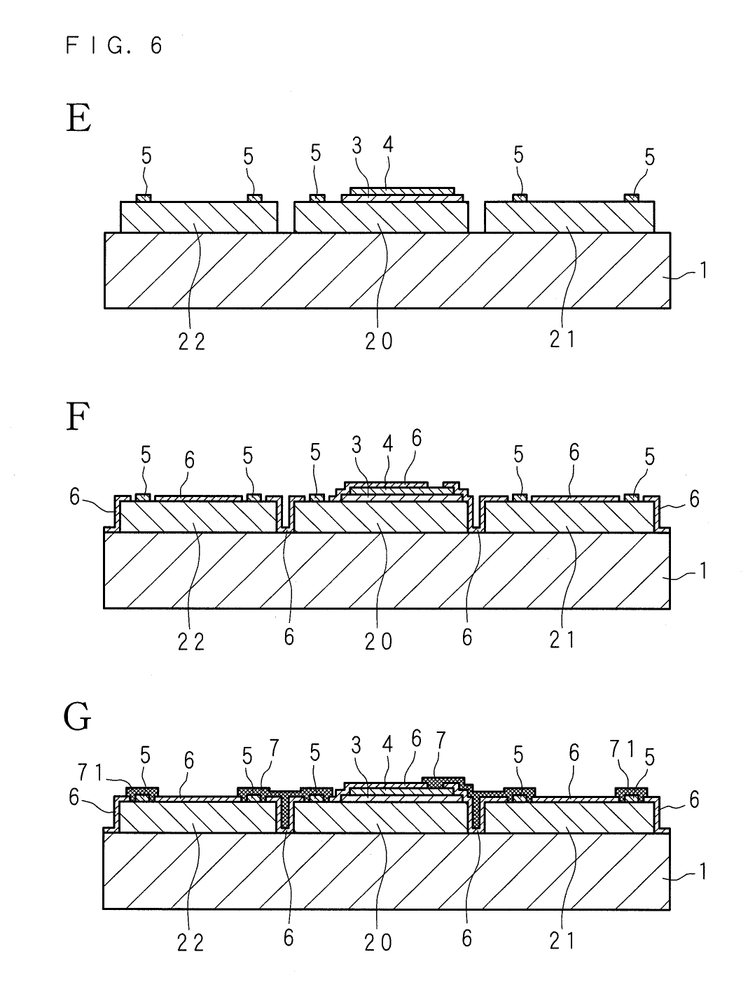

Next, a method for producing the semiconductor light-emitting element 100 according to the first embodiment will be described below. FIGS. 5 and 6 are an explanatory drawing of a process of producing the semiconductor light-emitting element 100. As shown in FIG. 5A, an AlN buffer layer (not shown) is first grown on the substrate (the sapphire substrate) 1 at 400° C. by metal organic chemical vapor deposition (MOCVD). Thereafter, a LED structure is made by forming the n-type semiconductor layer 2 (constituted by the about-2-μm-thick undoped GaN layer, the about-2-μm-thick n-GaN layer, the n-AlGaInN clad layer, etc.), the GaN/InGaN-MQW active layer (not shown), and the p-type semiconductor layer 3 (constituted by the p-AlGaInN layer, the about-0.3-μm-thick p-GaN layer, the p-InGaN layer as the contact layer, etc.) on the AlN buffer layer in that order. Then the substrate 1 is taken out of the MOCVD apparatus, and is heated to about 400° C. while being irradiated with ultraviolet light, whereby the p-type semiconductor layer 3 is made active.

As shown in FIG. 5B, a part of the n-type semiconductor layer 2 is exposed by removing the p-type semiconductor layer 3 at places for the formation of the resistance elements R1 and R2 and the LED structures (the LEDs 1 and 2) by using a photoresist at a mask through photolithography and dry etching. At that time, a pair of islands where independent PN junction is established are formed in a manner that provides a spacing between the islands. And further, a depth set for the etching is 400 nm, for example, and the thickness of the n-type semiconductor layers 2 as the resistance elements R1 and R2 formed by the etching is about 2.5 μm.

As shown in FIG. 5C, an about-400-nm-thick ITO (indium-tin oxide) film is deposited as the transparent current-diffusing layer 4 by using a deposition method such as vacuum evaporation or sputtering, following which patterning is carried out by using the lift-off method.

As shown in FIG. 5D, a V-Au-Al-Ni-Au film is deposited by vacuum evaporation, after which the n-type ohmic electrodes 5 are formed by carrying out patterning through the use of the lift-off method. Portions where the V-Au-Al-Ni-Au film is left, i.e., portions where the n-type ohmic electrodes 5 are to be formed are portions between which a proper spacing is provided of each upper surface of two portions of the n-type semiconductor layer 2 as the resistance elements R1 and R2 and portions where ohmic junction is to be established of the n-type semiconductor layer of the semiconductor layer (the LED structure). After the patterning, the wafer is put in a Schube furnace, and is heated to about 500° C. in a mixed nitrogen-oxygen atmosphere while annealing the n-type ohmic electrodes 5 and the current-diffusing layers 4.

Next, as shown in FIG. 6E, the n-type semiconductor layer 2 is etched by photolithography and dry etching until several parts of the sapphire substrate 1 are exposed in order to make the electrical division into the two LED structures (the LEDs 1 and 2) and the electrical division into the two resistance elements each constituted by the n-type semiconductor layer. As a result of the etching, the two divided n-type semiconductor layers 20 each constituting part of the LED structure are formed, and the n-type semiconductor layers 22 and 21 about 270 μm in length and about 15 μm in width are formed as the resistance elements.

As shown in FIG. 6F, a SiO₂ film is deposited on the entire upper surface of the wafer by plasma CVD. Thereafter, the SiO₂ film is removed at places where the bonding electrodes 71 are to be provided, places between the LEDs 1 and 2 where wiring is to be carried out, places where wiring for the resistance elements is to be carried out, and places between the semiconductor elements (the LED chips) by using a dilute fluoric acid.

As shown in FIG. 6G, a Ti-Au film is deposited by vacuum evaporation, and patterning is carried out through lift-off, whereby the bonding electrodes 71 and the wiring layers 7 are formed. As a result, a LED wafer is produced on which a plurality of LED chips are formed; within each package (each LED chip), the two resistance elements R1 and R2 and the two LED structures (the LEDs 1 and 2) connected in inverse parallel are provided.

Thereafter, element (LED chip) dicing is conducted by laser scribing, whereby semiconductor light-emitting elements (LED chips) are fabricated.

In this embodiment, a pair of LED structures (semiconductor layers) connected in inverse parallel are formed on one semiconductor light-emitting element 100; therefore, when having used one of the LED structures (e.g., the LED 1) as a light-emitting element, the other LED structure (e.g., the LED 2) reduces static electricity and overvoltage to be applied to the LED 1; thus the semiconductor light-emitting element 100 can be protected against static electricity and overvoltage without providing any external protective element, and a low component count, a space saving, and a low production cost can be achieved.

In the semiconductor light-emitting element 100 according to this embodiment, the n-type semiconductor layers 22 and 21 as the resistance elements having a proper length, width, and thickness are each provided on the substrate 1 at the foregoing spacing from the LED structure (the semiconductor layer), and the bonding electrode 71 and the n-type electrode 5 connected with the wiring layer 7 are formed on each upper surface of the n-type semiconductor layers 22 and 21 as the resistance elements with the foregoing spacing provided between the bonding electrode 71 and the n-type electrodes 5; therefore the resistance elements R1 and R2, which are respectively constituted by the n-type semiconductor layers 22 and 21, are respectively connected in series to the pair of LED structures (semiconductor layers) connected in inverse parallel, and are included in one semiconductor light-emitting element 100, and thus there is no need to provide an external resistance used to set the current value, whereby, a lower component count and a lower production cost can be achieved.

In this embodiment, the n-type semiconductor layers 22 and 21 as the resistance elements are about 270 μm in length, about 15 μm in width, and about 2.5 μm in thickness. A resistance value r can be found by using an expression r=a specific resistance×a length×a cross-sectional area. Since the specific resistance of the n-type semiconductor layers 22 and 21 is about 5.00×10⁻³ Ωcm, the resistance value r is about 360 Ω. Since the n-type semiconductor layers 22 and 21 are electrically connected in series, the resistance value r for the semiconductor light-emitting element 100 is about 720 Ω. And further, the resistance value r for the semiconductor light-emitting element 100 can be set at 100 Ω to 5000 Ω, for example, by suitably changing concentrations of impurities in the n-type semiconductor layers 22 and 21 and the lengths, widths, and thicknesses of the n-type semiconductor layers 22 and 21. By setting the resistance value r for the semiconductor light-emitting element 100 at 100 Ω to 5000 Ω, the semiconductor light-emitting element 100 can emit light with desired brightness in accordance with power supply voltage. In a case where the resistance value r is smaller than 100 Ω, an overcurrent flows through the semiconductor light-emitting element 100, and thus it is desirable to use a power supply that generates low power supply voltage. In contrast, in a case where the resistance value r is larger than 5000 Ω, since the current value is small, it is difficult to obtain sufficient brightness, and thus it is desirable to use a power supply that generates high power supply voltage.

Since the resistance value r can be suitably set, there is no need to design a circuit for setting the value of a current to be passed through the LEDs to obtain desired brightness. Therefore desired brightness can be obtained just by applying a predetermined voltage.

In this embodiment, the substrate 1 is shaped into a rectangle, the LED structures (the semiconductor layers) are formed near the ends of one diagonal line of the upper surface of the substrate 1, the bonding electrodes 71 are formed near the ends of the other diagonal line of the upper surface of the substrate 1, and the n-type semiconductor layers 22 and 21 as the resistance elements are formed near opposite two sides of the upper surface of the substrate 1; that is, two LED structures and two resistance elements can be included in one package, and one of the LED structures functions as a protective elements that protects the other LED structure against static electricity and overvoltage; therefore, a semiconductor light-emitting element can be implemented to which there is no need to provide an external circuit, which can be protected against static electricity and overvoltage, and from which desired brightness can be obtained just by applying a predetermined voltage.

In general, circuit design is performed such that direct current is passed through light-emitting diodes; however, since the semiconductor light-emitting elements 100 according to this embodiment includes two LED structures connected in inverse parallel, the kind of driving voltage is not limited to direct voltage, that is, the semiconductor light-emitting element 100 can also be AC-driven by applying AC voltage.

### Second Embodiment

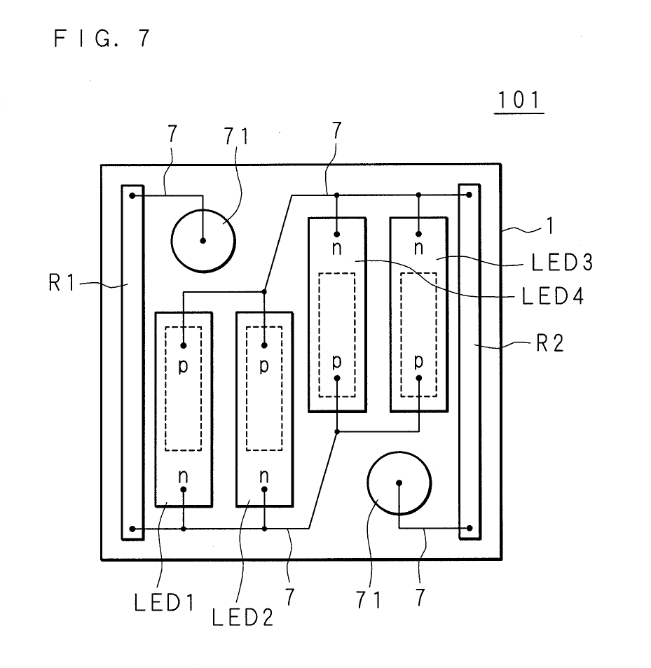

FIG. 7 is a schematic view of a semiconductor light-emitting element 101 according to a second embodiment of the present invention showing an exemplary arrangement of various components. In the first embodiment, the two LED structures (the LEDs 1 and 2) are connected in inverse parallel as shown in FIG. 4; however, the arrangement of the LED structures is not limited to the arrangement depicted in the first embodiment. In the second embodiment, another LED is connected in parallel to the LED 1 and the LED2 of the first embodiment. That is, as shown in FIG. 7, the semiconductor light-emitting element 101 according to the second embodiment has a configuration in which the LEDs 1 and 2 connected in parallel are connected in inverse parallel with the LEDs 3 and 4 connected in parallel.

A method for producing the semiconductor light-emitting element 101 is the same as the production method described in the first embodiment except that the four divided LEDs are formed, and thus description of such a method will be omitted.

Even if one of the two LED structures connected in parallel gets broken at the semiconductor light-emitting element 101 having such a configuration, light emission can be continued by the other LED structure, that is, light emission can be maintained without completely going out as one semiconductor light-emitting element (LED chip).

In the first and second embodiments, the two divided n-type semiconductor layers are formed as the resistance elements; however, an arrangement of each n-type semiconductor layer is not limited to such an arrangement. For example, just one resistance element can also be provided by forming a single n-type semiconductor layer.

In the second embodiment, the LEDs 1 and 2 are connected in parallel and the LEDs 3 and 4 are connected in parallel; however, their arrangement is not limited to such an arrangement. For example, an arrangement may be done in which the LEDs 1 and 2 connected in series are connected in inverse parallel with the LEDs 3 and 4 connected in series.

### Third Embodiment

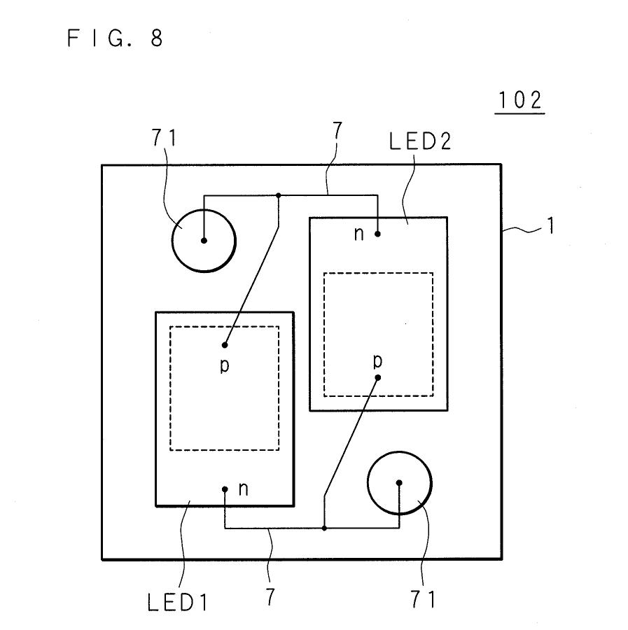

FIG. 8 is a schematic view of a semiconductor light-emitting element 102 according to a third embodiment of the present invention showing an exemplary arrangement of several components. The semiconductor light-emitting element 102 according to the third embodiment differs from the light-emitting elements 100 and 101 according to the first and second embodiments in that no n-type semiconductor layers as resistance elements are provided.

As shown in FIG. 8, two divided semiconductor structures (the LEDs 1 and 2) are provided on the substrate 1 by laminating an n-type semiconductor layer, an active layer, and a p-type semiconductor layer, the wiring layer 7 is provided in a manner that connects the n-type semiconductor layer of one of the LED structures (the LED 1) and the p-type semiconductor layer of the other LED structure (the LED 2), and the bonding electrode 71 connected to the wiring layer 7 is provided. Likewise, another bonding electrode 71 is connected to another wiring layer 7 connecting the p-type semiconductor layer of one of the LED structures (the LED 1) and the n-type semiconductor layer of the other LED structure (the LED 2). That is, a pair of LED structures (semiconductor layers) connected in inverse parallel are provided on one semiconductor light-emitting element 102; therefore, when having used one of the LED structures as a light-emitting element, the other LED structure decreases static electricity and overvoltage to be applied to the former LED structure. Thus the semiconductor light-emitting element 102 can be prevented against static electricity and overvoltage without providing any external protective element, and moreover, a low component count, a space saving, and a low production cost can be achieved.

In the first embodiment, the pair of LED structures, i.e., the LEDs 1 and 2 (the semiconductor layers) connected in inverse parallel and the two resistance elements R1 and R2 respectively connected in series to the LED structures are provided as shown in FIGS. 1 to 4; however, the arrangement of the components of the semiconductor light-emitting element is not limited to the above arrangement. For example, the semiconductor light-emitting element can also be configured with a single resistance element R1 and a single LED 1. In that case, the semiconductor light-emitting element includes a first bonding electrode connected to one of the n-type and p-type semiconductor layers (e.g., the p-type semiconductor layer) of the semiconductor layer (the LED 1), an n-type semiconductor layer (R1) as a first resistance element formed on the substrate 1 at a spacing from the semiconductor layer (the LED 1), a second bonding electrode and a first electrode that are formed on the upper surface of the n-type semiconductor layer as the first resistance element with a spacing provided between the two electrodes, and a first wiring layer connecting the first electrode and the other semiconductor layer (e.g., the n-type semiconductor layer) of the semiconductor layer (the LED 1). Since the single resistance element R1 and the single LED 1 are provided, there is no need to provide an external resistance element for setting a current value, and thus a lower component count, a further space saving, and a lower production cost can be achieved; and moreover, there is no need to design a circuit for setting the value of a current to be passed through the LED 1 to obtain desired brightness, and the desired brightness can, therefore, be obtained just by applying a predetermined voltage. In this embodiment, the LED2 can be further provided in addition to the resistance element R1 and the LED 1. In that case, the semiconductor light-emitting element is provided with not only an additional semiconductor layer (the LED 2) formed on the substrate 1 at a spacing from the semiconductor layer (the LED 1) but a second wiring layer connecting the n-type semiconductor layer of the semiconductor layer (the LED 1) and the p-type semiconductor layer of the additional semiconductor layer (the LED 2) and connecting the p-type semiconductor layer of the semiconductor layer (the LED 1) and the n-type semiconductor layer of the additional semiconductor layer (the LED 2). In the configuration in which the LED 2 is further provided in addition to the resistance element R1 and the LED 1, when having used one of the LED structures as a light-emitting element, the other LED structure decreases static electricity and overvoltage to be applied to the former LED structure, and the semiconductor light-emitting element can, therefore, be protected against static electricity and overvoltage without providing any external protective element; and moreover, a low component count, a space saving, a low production cost, etc. can be achieved.

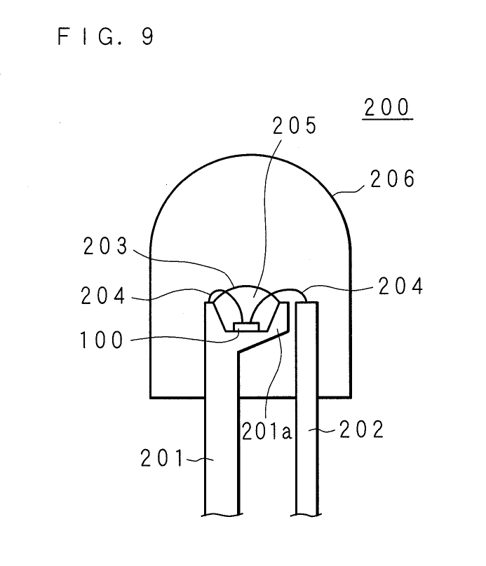

FIG. 9 is a schematic view of a light-emitting device 200 according to another embodiment of the present invention showing an exemplary structure of the light-emitting device 200. The light-emitting device 200 is a light-emitting diode, and has a housing portion in which any one of the foregoing semiconductor light-emitting elements 100, 101, and 102 is housed.

As shown in FIG. 9, the light-emitting device (the light-emitting diode) 200 includes leadframes 201 and 202; at one end of the leadframe 201, a concave portion 201a as the housing portion is provided. To the bottom surface of the concave portion 201a, the semiconductor light-emitting element (the LED chip) 100 is fixedly adhered by die bonding.

One of the bonding electrodes of the LED chip 100 is wire-bonded to the leadframe 201 by using a wire 204, and the other bonding electrode is wire-bonded to the leadframe 202 by using another wire 204. By filling the concave portion 201a with a translucent resin, a cover portion 203 for covering the LED chip 100 is formed. And further, in the cover portion 203, it is also possible to include a fluorescent material 205 that produces light of a color corresponding to the color of light to be emitted by the LED chip 100.

The end of the leadframe 201 at which the cover portion 203 is provided and the end of the leadframe 202 are placed in a lens 206 having a convex head. The lens 206 is made of a translucent resin such as an epoxy resin.

The light-emitting device (the light-emitting diode) 200 houses the semiconductor light-emitting element 100. By doing so, a light-emitting device can be provided which can be protected against static electricity and overvoltage, in which a low component count and a space saving can be achieved because there is no need to provide an external resistance element and an external protective element to the device, and which can, therefore, be fabricated at a low cost.

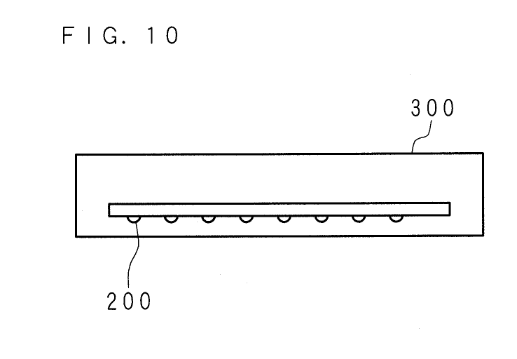

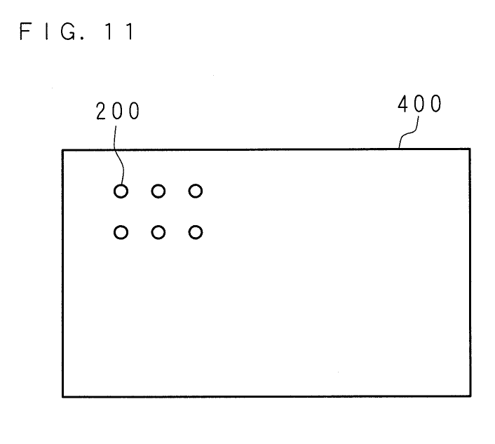

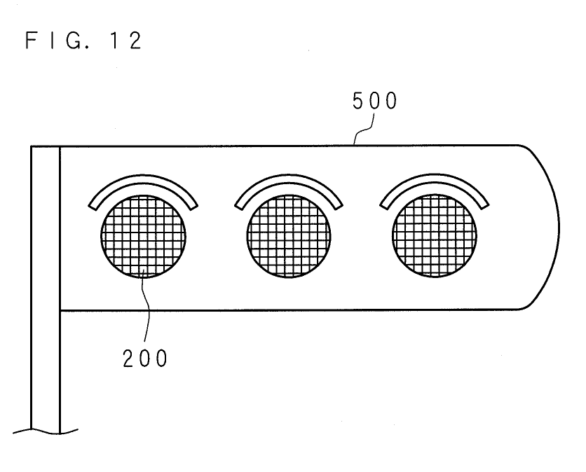

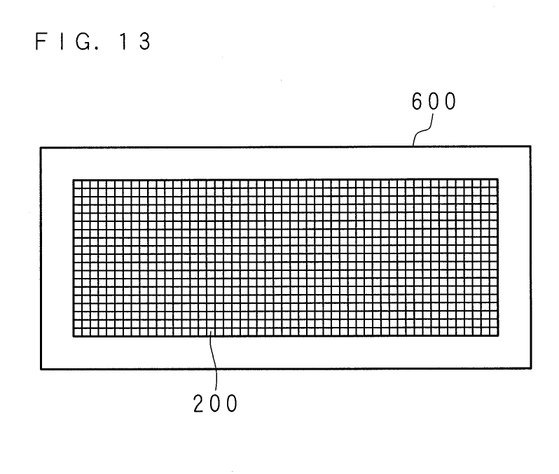

It is also possible to mount a circuit board on which the light-emitting diodes 200 are mounted in large numbers and a power-supply unit that feeds a predetermined voltage to the light-emitting diodes 200 in order to obtain desired brightness, etc. to apparatus such as a luminaire 300 of FIG. 10, a display unit 400 of FIG. 11, a traffic signal lamp unit 500 of FIG. 12, and a traffic information display unit 600 of FIG. 13. For example, the luminaire 300, the display unit 400, the traffic signal lamp unit 500, and the traffic information display unit 600 are each provided with the light-emitting devices (the light-emitting diodes) 200 according to above embodiment as a light source. Therefore a luminaire, a display unit, a traffic signal lamp unit, and a traffic information display unit can be provided which can be protected from static electricity and overvoltage, in which low component counts and space savings can be achieved, and which can be fabricated at low costs.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

What is claimed is:

1. A semiconductor light-emitting element in which a semiconductor layer, which is made by laminating an n-type semiconductor layer, an active layer, and a p-type semiconductor layer, is provided on a substrate, the semiconductor light-emitting element comprising:
a first bonding electrode connected to one of the n-type and p-type semiconductor layers of the semiconductor layer;
an n-type semiconductor layer as a first resistance element dividedly formed of the semiconductor layer on the substrate;
a second bonding electrode and a first electrode that are formed on the upper surface of the n-type semiconductor layer as the first resistance element with a spacing provided between both the electrodes; and
a first wiring layer connecting the first electrode and the other-type semiconductor layer of the semiconductor layer.

2. The semiconductor light-emitting element according to claim 1, the element further comprising:
another semiconductor layer dividedly formed of the semiconductor layer on the substrate; and
a second wiring layer connecting the n-type semiconductor layer of the semiconductor layer and the p-type semiconductor layer of the divided semiconductor layer and connecting the p-type semiconductor layer of the semiconductor layer and the n-type semiconductor layer of the divided semiconductor layer.

3. The semiconductor light-emitting element according to claim 1, the element further comprising:
an n-type semiconductor layer as a second resistance element dividedly formed of the semiconductor layer on the substrate;
the first bonding electrode and a second electrode that are formed on the upper surface of the n-type semiconductor layer as the second resistance element with a spacing provided between both the electrodes; and
a third wiring layer connecting the second electrode and any one of the n-type and p-type semiconductor layers of the semiconductor layer.

4. The semiconductor light-emitting element according to claim 2, the element further comprising:
an n-type semiconductor layer as a second resistance element dividedly formed of the semiconductor layer on the substrate;
the first bonding electrode and a second electrode that are formed on the upper surface of the n-type semiconductor layer as the second resistance element; and
a third wiring layer connecting the second electrode and any one of the n-type and p-type semiconductor layer of the semiconductor layer.

5. The semiconductor light-emitting element according to claim 2,
wherein the substrate is shaped into a rectangle,
the semiconductor layers are respectively formed near the ends of one diagonal line of the upper surface of the substrate,
the bonding electrodes are respectively formed near the ends of the other diagonal line of the upper surface of the substrate, and
the n-type semiconductor layer as the resistance element is formed near at least one side of the upper surface of the substrate.

6. The semiconductor light-emitting element according to claim 3,
wherein the substrate is shaped into a rectangle,
the semiconductor layers are respectively formed near the ends of one diagonal line of the upper surface of the substrate,
the bonding electrodes are respectively formed near the ends of the other diagonal line of the upper surface of the substrate, and
the n-type semiconductor layer as the resistance element is formed near at least one side of the upper surface of the substrate.

7. The semiconductor light-emitting element according to claim 4,
wherein the substrate is shaped into a rectangle,
the semiconductor layers are respectively formed near the ends of one diagonal line of the upper surface of the substrate,
the bonding electrodes are respectively formed near the ends of the other diagonal line of the upper surface of the substrate, and
the n-type semiconductor layer as the resistance element is formed near at least one side of the upper surface of the substrate.

8. The semiconductor light-emitting element according to claim 1,
wherein a resistance value for the n-type semiconductor layer as the resistance element is 100 Ω to 5000 Ω.

9. The semiconductor light-emitting element according to claim 2,
wherein a resistance value for the n-type semiconductor layer as the resistance element is 100 Ω to 5000 Ω.

10. The semiconductor light-emitting element according to claim 3,
wherein a resistance value for the n-type semiconductor layer as the resistance element is 100 Ω to 5000 Ω.

11. The semiconductor light-emitting element according to claim 4,
wherein a resistance value for the n-type semiconductor layer as the resistance element is 100 Ω to 5000 Ω.

12. A light-emitting device comprising:
the semiconductor light-emitting element according to claim 1; and
a housing portion in which the semiconductor light-emitting element is housed.

13. A luminaire comprising the light-emitting devices according to claim 12.

14. A display unit comprising the light-emitting devices according to claim 12.

15. A traffic signal lamp unit comprising the light-emitting devices according to claim 12.

16. A traffic information display unit comprising the light-emitting devices according to claim 12.
